(19) United States
(12) Patent Application Publication
(10) Pub. No.: US 2010/0265009 A1
(43) Pub. Date: Oct. 21, 2010

(54) STACKED LC RESONATOR AND BANDPASS FILTER OF USING THE SAME

(75) Inventors: Tzyy-Sheng Horng, Kaohsiung City (TW); Chien-Hsun Chen, Kaohsiung City (TW); Chien-Hsiang Huang, Kaohsiung City (TW); Sung-Mao Wu, Kaohsiung City (TW); Chi-Tsung Chiu, Kaohsiung City (TW); Chih-Pin Hung, Kaohsiung City (TW)

Correspondence Address: Muncy, Geissler, Olds & Lowe, PLLC, 4000 Legato Road, Suite 310, FAIRFAX, VA, 22033, US

(73) Assignee: National Sun Yat-Sen University, Kaohsiung City (TW)

(21) Appl. No.: 12/425,045

(22) Filed: Apr. 16, 2009

(51) Int. Cl. H03H 7/01; H03H 7/12

(52) U.S. Cl. 333/185

(57) ABSTRACT

A stacked LC resonator includes a parallel-plate capacitor, a dielectric layer and a spiral inductor. The parallel-plate capacitor has a first metal layer, a second metal layer opposed to the first metal layer and a middle dielectric layer formed between the first and second metal layers. The dielectric layer is formed on the second metal layer of the parallel-plate capacitor. The spiral inductor is formed on the dielectric layer and electrically connected with the first and second metal layers of the parallel-plate capacitor.

### FIELD OF THE INVENTION

The present invention generally relates to a stacked LC resonator and bandpass filter of using it.

### BACKGROUND OF THE INVENTION

Bandpass filter is a very important part in the field of overall wireless system, especially a bandpass filter having better performance can effectively restrain frequency interference to raise communication quality substantially. Besides, transmission-zero of frequency response of bandpass filter may also help to improve stop-band response that can increase selectivity of frequency response. Bandpass filter is designed not only for high electrical efficiency but also for low production cost and miniaturization of components so as to be well suited for use in wireless apparatus. Typically, almost all of the coupling bandpass filters have been fabricated adopting transmission lines, however, it generally needs to use operating frequency at half-wavelength or quarter-wavelength for making a transmission line have efficiency equivalent to a resonator. Unfortunately, this method could be disadvantage of circuit miniaturization. Furthermore, in case of changing transmission-zero after designing and fabricating traditional bandpass filter, it is usually required to add extra components, transmission lines and quarter-wavelength resulting in inconvenience for use in applications and substantial increase of production cost.

### SUMMARY OF THE INVENTION

A primary object of the present invention is to provide a stacked LC resonator and a bandpass filter of using the resonator. The stacked LC resonator includes a parallel-plate capacitor, a dielectric layer and a spiral inductor. The parallel-plate capacitor has a first metal layer, a second metal layer opposed to the first metal layer and a middle dielectric layer formed between the first and second metal layers. The dielectric layer is formed on the second metal layer of the parallel-plate capacitor. The spiral inductor is formed on the dielectric layer and electrically connected with the first and second metal layers of the parallel-plate capacitor. The bandpass filter includes an input-side stacked LC resonator, an output-side stacked LC resonator, an input feeder and an output feeder. The input-side stacked LC resonator includes a first parallel-plate capacitor, a first dielectric layer and a first spiral inductor. The first parallel-plate capacitor has a first metal layer, a second metal layer opposed to the first metal layer and a first middle dielectric layer formed between the first and second metal layers. The first dielectric layer is formed on the second metal layer of the first parallel-plate capacitor. The first spiral inductor is formed on the first dielectric layer and electrically connected with the first and second metal layers of the first parallel-plate capacitor. The output-side stacked LC resonator includes a second parallel-plate capacitor, a second dielectric layer and a second spiral inductor. The second parallel-plate capacitor has a third metal layer connected with the first metal layer, a fourth metal layer opposed to the third metal layer and a second middle dielectric layer formed between the third and fourth metal layers. The second dielectric layer is formed on the fourth metal layer of the second parallel-plate capacitor. The second spiral inductor is formed on the second dielectric layer and electrically connected with the third and fourth metal layer of the second parallel-plate capacitor. The input feeder is connected with the first spiral inductor of the input-side stacked LC resonator and the output feeder is connected with the second spiral inductor of the output-side stacked LC resonator. Because resonant frequency of the stacked LC resonator can be formed by collocating any value of inductance and capacitance, there are lots of options in designation of the resonator, as well as, it is definitely available to substantially reduce area of a singular resonator as compared to conventional microstrip resonator which has efficiency equivalent to utilizing half-wavelength or quarter-wavelength and even more helpful for miniaturizing area after constructing the bandpass filter. Moreover, transmission-zero location of the bandpass filter of the present invention can also be adjusted through a transmission-zero adjusting slot formed at the ground layer, so that adding any extra component, transmission line or modifying original structure of filter is no longer needed for transmission-zero adjustment and such adjustment by utilizing the transmission-zero adjusting slot has no obvious effect on insertion loss and frequency bandwidth in the pass-band.

### DESCRIPTION OF THE DRAWINGS

FIG. 1 depicts a stacked LC resonator structure in accordance with a preferred embodiment of the present invention.

FIG. 2 depicts a 2^{nd}-order bandpass filter structure in accordance with a preferred embodiment of the present invention.

FIG. 3 depicts scattering parameter measurement results of that before and after the 2^{nd}-order bandpass filter is adjusted through a transmission-zero adjusting slot.

FIG. 4 depicts a 4^{th}-order bandpass filter structure in accordance with another embodiment of the present invention.

### DETAILED DESCRIPTION OF THE PRESENT INVENTION

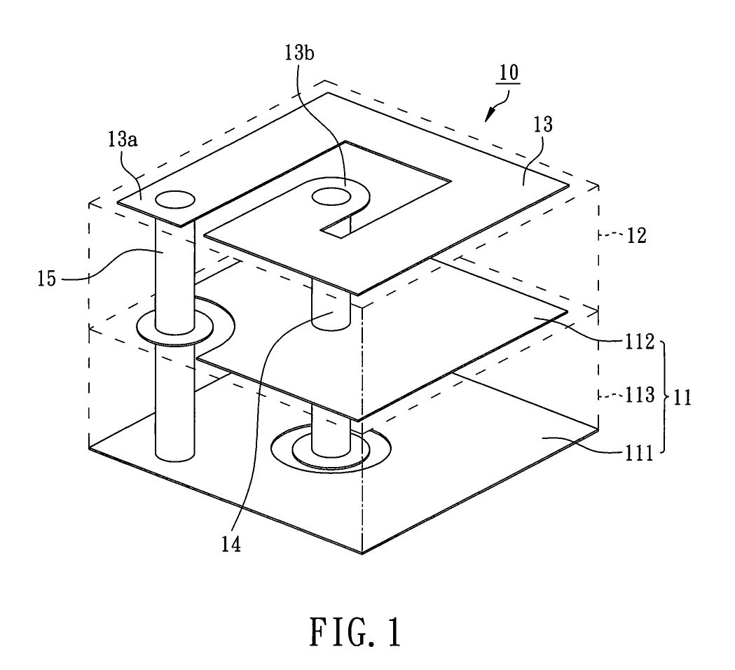

FIG. 1 shows a preferred embodiment of a stacked LC resonator 10 of the present invention including a parallel-plate capacitor 11, a dielectric layer 12, a spiral inductor 13, a first conductive pillar 14 and a second conductive pillar 15. The parallel-plate capacitor 11 has a first metal layer 111, a second metal layer 112 opposed to the first metal layer 112 and a middle dielectric layer 113 formed between the first and second metal layers 111, 112. The dielectric layer 12 is formed on the second metal layer 112 of the parallel-plate capacitor 11. The spiral inductor 13 is formed on the dielectric layer 12 and electrically connected with the first and second metal layers 111, 112 of the parallel-plate capacitor 11, and has a first end portion 13a and a second end portion 13b in this embodiment. The first conductive pillar 14 penetrates the middle dielectric layer 113 and the dielectric layer 12 and two ends of the first conductive pillar 14 are connected with the spiral inductor 13 and the first metal layer 111 of the parallel-plate capacitor 11 respectively, and preferably one end of it is connected with the first end portion 13a of the spiral inductor 13. Likewise, the second conductive pillar 15 penetrates the dielectric layer 12 and two ends of the second conductive pillar 15 are connected with the spiral inductor 13 and the second metal layer 112 of the parallel-plate capacitor 11 respectively, and preferably one end of it is connected with the second end portion 13b of the spiral inductor 13. Besides, the first and second conductive pillars 14, 15 may be hollow or solid in this embodiment. Because resonant frequency of the stacked LC resonator 10 can be formed by collocating any value of inductance and capacitance, there are lots of options in designation of the resonator, as well as, it is definitely available to substantially reduce area of a singular resonator as compared to conventional microstrip resonator which has efficiency equivalent to utilizing half-wavelength or quarter-wavelength.

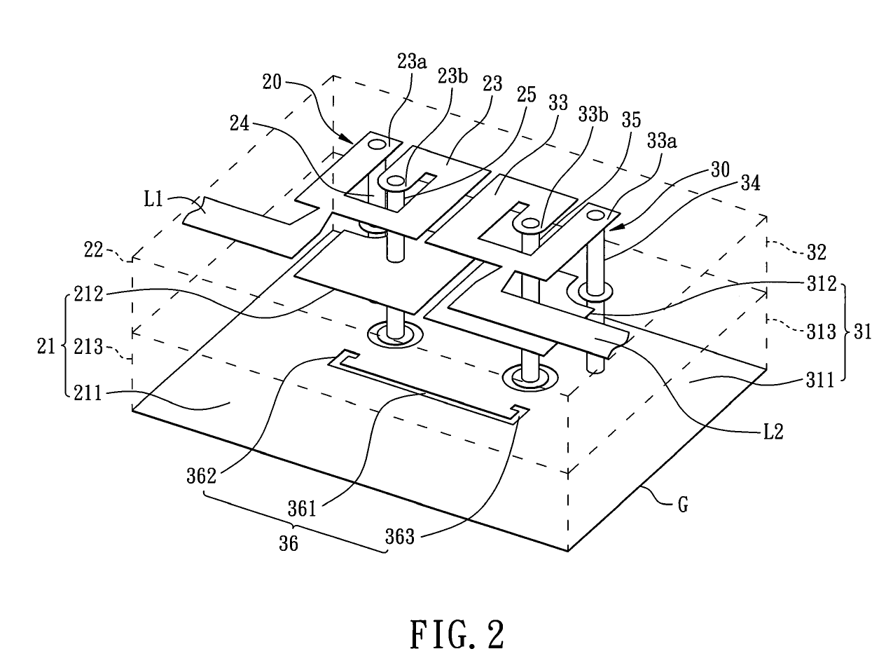

FIG. 2 shows a bandpass filter composed of stacked LC resonator of the present invention and which is a 2^{nd}-order bandpass filter composed of two resonators with stacked inductor and capacitor in this embodiment including an input-side stacked LC resonator 20, an output-side stacked LC resonator 30, an input feeder L1 and an output feeder L2. The input-side stacked LC resonator 20 includes a first parallel-plate capacitor 21, a first dielectric layer 22, a first spiral inductor 23, a first conductive pillar 24 and a second conductive pillar 25. The first parallel-plate capacitor 21 has a first metal layer 211, a second metal layer 212 opposed to the first metal layer 211 and a first middle dielectric layer 231 formed between the first and second metal layers 211, 212. The first dielectric layer 22 is formed on the second metal layer 212 of the first parallel-plate capacitor 21. The first spiral inductor 23 is formed on the first dielectric layer 22 and electrically connected with the first and second metal layers 211, 212 of the first parallel-plate capacitor 21 and has a first end portion 23a and a second end portion 23b. The first conductive pillar 24 penetrates the first middle dielectric layer 213 and the first dielectric layer 22 and two ends of the first conductive pillar 24 are connected with the first spiral inductor 23 and the first metal layer 211 of the first parallel-plate capacitor 21 respectively, and preferably one end of it is connected with the first end portion 23a of the first spiral inductor 23. Likewise, the second conductive pillar 25 penetrates the first dielectric layer 22 and two ends of the second conductive pillar 25 are connected with the first spiral inductor 23 and the second metal layer 212 of the first parallel-plate capacitor 21 respectively, and preferably one end of it is connected with the second end portion 23b of the first spiral inductor 23. Moreover, the first and second conductive pillars 24, 25 may be hollow or solid in this embodiment.

With reference again to FIG. 2, the output-side stacked LC resonator 30 includes a second parallel-plate capacitor 31, a second dielectric layer 32, a second spiral inductor 33, a third conductive pillar 34 and a fourth conductive pillar 35. The second parallel-plate capacitor 31 has a third metal layer 311 connected with the first metal layer 211, a fourth metal layer 312 opposed to the third metal layer 311 and a second middle dielectric layer 313 formed between the third and fourth metal layers 311, 312, wherein the first metal layer 211 of the first parallel-plate capacitor 21 and the third metal layer 311 of the second parallel-plate capacitor 31 form a ground layer G. The second dielectric layer 32 is formed on the fourth metal layer 312 of the second parallel-plate capacitor 31. The second spiral inductor 33 is formed on the second dielectric layer 32 and electrically connected with the third and fourth metal layers 311, 312 of the second parallel-plate capacitor 31, and has a third end portion 33a and a fourth end portion 33b in this embodiment. The third conductive pillar 34 penetrates the second middle dielectric layer 313 and the second dielectric layer 32 and two ends of the third conductive pillar 34 are connected with the second spiral inductor 33 and the third metal layer 311 of the second parallel-plate capacitor 31 respectively, and preferably one end of it is connected with the third end portion 33a of the second spiral inductor 33. Likewise, the fourth conductive pillar 35 penetrates the second dielectric layer 32 and two ends of the fourth conductive pillar 35 are connected with the second spiral inductor 33 and the fourth metal layer 312 of the second parallel-plate capacitor 31 respectively, and preferably one end of it is connected with the fourth end portion 33b of the second spiral inductor 33. Besides, the third and fourth conductive pillars 34, 35 may be hollow or solid in this embodiment. The input feeder L1 is connected with the first spiral inductor 23 of the input-side stacked LC resonator 20 and the output feeder L2 is connected with the second spiral inductor 33 of the output-side stacked LC resonator 30.

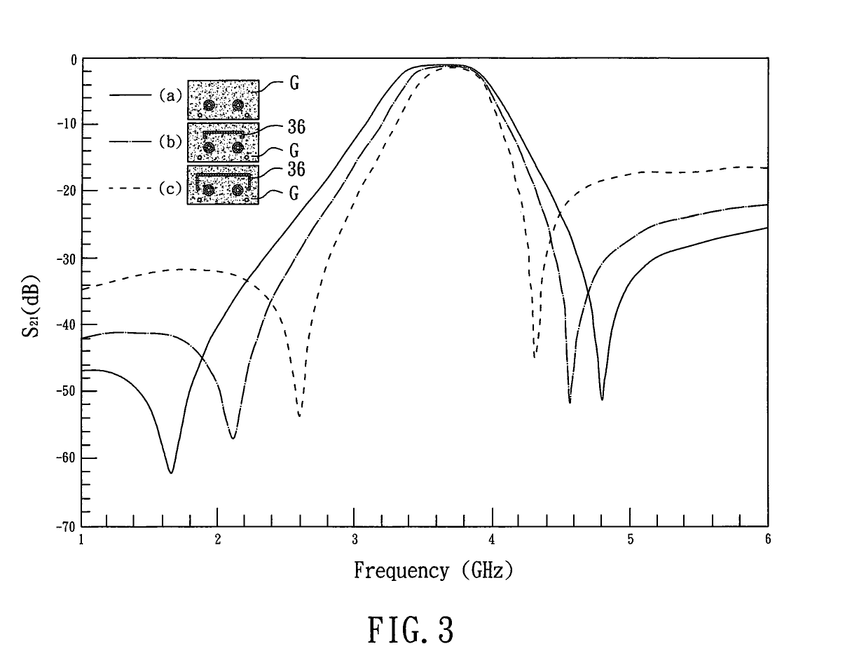

With reference again to FIG. 2, the bandpass filter further has a transmission-zero adjusting slot 36, which is formed on the ground layer G to adjust transmission-zero frequency. The transmission-zero location generated by the fed can be adjusted by controlling length and geometric form of the transmission-zero adjusting slot 36. The transmission-zero adjusting slot 36 is preferably in shape of “C” and has a longitudinal slot portion 361, a first transverse slot portion 362 formed at one end of the longitudinal slot portion 361 and a second transverse slot portion 363 formed at another end of the longitudinal slot portion 361. In this embodiment, the longitudinal slot portion 361, the first transverse slot portion 362 and the second transverse slot portion 363 may have same or different lengths. FIG. 3 shows scattering parameter measurement result of that before and after the bandpass filter is adjusted by the transmission-zero adjusting slot 36, it should be noted that transmission-zero location is obviously changed after adjusting the bandpass filter through the transmission-zero adjusting slot 36, and transmission-zero locations which respectively correspond to different lengths of the transmission-zero adjusting slot 36 are different. In addition, such adjustment by utilizing the transmission-zero adjusting slot 36 has no obvious effect on insertion loss and frequency bandwidth in the pass-band.

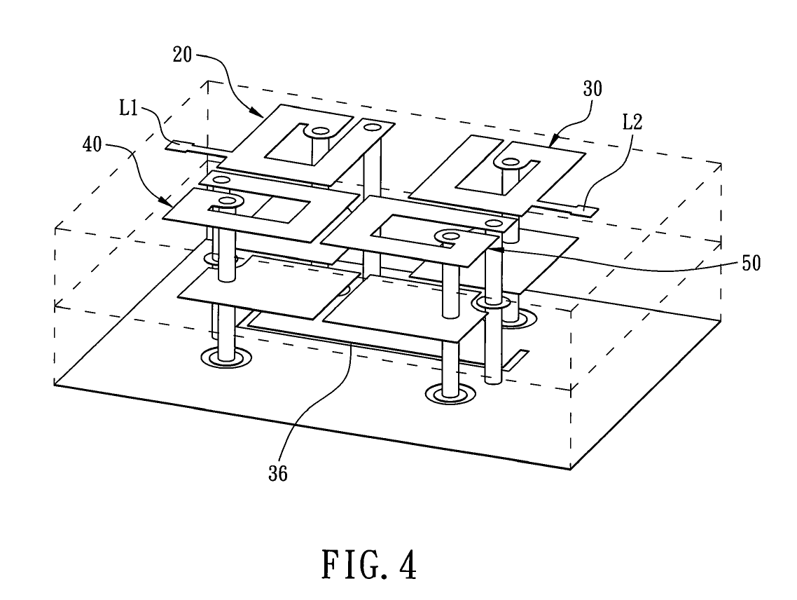

FIG. 4 shows a bandpass filter in accordance with another embodiment of the present invention, which is a 4^{th}-order pass-band filter composed of four resonators with stacked inductor and capacitor in this embodiment. The bandpass filter of this embodiment has same basic composition as the 2^{nd}-order pass-band filter mentioned above does with the exception of adding two more resonators with stacked inductor and capacitor. Besides, the bandpass filter of this embodiment also can serve transmission-zero adjustment by utilizing the transmission-zero adjusting slot 36 without adding any extra component, transmission line or modifying original structure of filter, which may raise convenience for use in application and decrease production cost.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A stacked LC resonator comprising:
a parallel-plate capacitor having a first metal layer, a second metal layer opposed to the first metal layer and a middle dielectric layer formed between the first and second metal layers;
a dielectric layer formed on the second metal layer of the parallel-plate capacitor; and
a spiral inductor formed on the dielectric layer and electrically connected with the first and second metal layers of the parallel-plate capacitor.

2. The stacked LC resonator in accordance with claim 1, further comprising a first conductive pillar, two ends of which being connected with the spiral inductor and the first metal layer of the parallel-plate capacitor respectively.

3. The stacked LC resonator in accordance with claim 2, wherein the spiral inductor has a first end portion and a second end portion, one end of the first conductive pillar is connected with the first end portion of the spiral inductor.

4. The stacked LC resonator in accordance with claim 2, wherein the first conductive pillar penetrates the middle dielectric layer and the dielectric layer.

5. The stacked LC resonator in accordance with claim 2, further comprising a second conductive pillar, two ends of which being connected with the spiral inductor and the second metal layer of the parallel-plate capacitor respectively.

6. The stacked LC resonator in accordance with claim 5, wherein the spiral inductor has a first end portion and a second end portion, one end of the second conductive pillar is connected with the second end portion of the spiral inductor.

7. A bandpass filter comprising:
an input-side stacked LC resonator comprising:
a first parallel-plate capacitor having a first metal layer, a second metal layer opposed to the first metal layer and a first middle dielectric layer formed between the first and second metal layers;
a first dielectric layer formed on the second metal layer of the first parallel-plate capacitor; and
a first spiral inductor formed on the first dielectric layer and electrically connected with the first and second metal layers of the first parallel-plate capacitor;
an output-side stacked LC resonator comprising:
a second parallel-plate capacitor having a third metal layer connected with the first metal layer, a fourth metal layer opposed to the third metal layer and a second middle dielectric layer formed between the third and fourth metal layers;
a second dielectric layer formed on the fourth metal layer of the second parallel-plate capacitor; and
a second spiral inductor formed on the second dielectric layer and electrically connected with the third and fourth metal layers of the second parallel-plate capacitor;
an input feeder connected with the first spiral inductor of the input-side stacked LC resonator; and
an output feeder connected with the second spiral inductor of the output-side stacked LC resonator.

8. The bandpass filter in accordance with claim 7, wherein the first metal layer of the first parallel-plate capacitor and the third metal layer of the second parallel-plate capacitor form a ground layer.

9. The bandpass filter in accordance with claim 8, further comprising a transmission-zero adjusting slot formed on the ground layer.

10. The bandpass filter in accordance with claim 9, wherein the transmission-zero adjusting slot is in shape of “C”.

11. The bandpass filter in accordance with claim 9, wherein the transmission-zero adjusting slot has a longitudinal slot portion, a first transverse slot portion formed at one end of the longitudinal slot portion and a second transverse slot portion formed at another end of the longitudinal slot portion.

12. The bandpass filter in accordance with claim 7, wherein the input-side stacked LC resonator further includes a first conductive pillar, two ends of the first conductive pillar are connected with the first spiral inductor and the first metal layer of the first parallel-plate capacitor respectively.

13. The bandpass filter in accordance with claim 12, wherein the first spiral inductor has a first end portion and a second end portion, one end of the first conductive pillar is connected with the first end portion of the first spiral inductor.

14. The bandpass filter in accordance with claim 12, wherein the first conductive pillar penetrates the first middle dielectric layer and the first dielectric layer.

15. The bandpass filter in accordance with claim 12, wherein the input-side stacked LC resonator further includes a second conductive pillar, two ends of the second conductive pillar are connected with the first spiral inductor and the second metal layer of the first parallel-plate capacitor respectively.

16. The bandpass filter in accordance with claim 15, wherein the first spiral inductor has a first end portion and a second end portion, one end of the second conductive pillar is connected with the second end portion of the first spiral inductor.

17. The bandpass filter in accordance with claim 16, wherein the output-side stacked LC resonator further includes a third conductive pillar, two ends of the third conductive pillar are connected with the second spiral inductor and the third metal layer of the second parallel-plate capacitor respectively.

18. The bandpass filter in accordance with claim 17, wherein the second spiral inductor has a third end portion and a fourth end portion, one end of the third conductive pillar is connected with the third end portion of the second spiral inductor.

19. The bandpass filter in accordance with claim 17, wherein the third conductive pillar penetrates the second middle dielectric layer and the second dielectric layer.

20. The bandpass filter in accordance with claim 17, wherein the output-side stacked LC resonator further includes a fourth conductive pillar, two ends of the fourth conductive pillar are connected with the second spiral inductor and the fourth metal layer of the second parallel-plate capacitor respectively.
